(19) United States
(12) Patent Application Publication
(10) Pub. No.: US 2007/0224800 A1
(43) Pub. Date: Sep. 27, 2007

(54) PRODUCTION METHOD FOR SEMICONDUCTOR DEVICE

(75) Inventor: Kei Miyoshi, Annaka-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Shin-Etsu Chemical Co., Ltd., Chiyoda-ku (JP)

(21) Appl. No.: 11/689,133

(22) Filed: Mar. 21, 2007

(30) Foreign Application Priority Data
Mar. 22, 2006 (JP) 2006-078367

(51) Int. Cl. H01L 21/44; H01L 21/31; H01L 21/469

(52) U.S. Cl. 438/617; 438/780; 257/E23.12; 257/E21.509

(57) ABSTRACT

A method for producing a semiconductor device that uses a silicone-based die bonding material with high heat resistance and a low elastic modulus is provide. The method includes the steps of: applying a heat-curable silicone-based die bonding material to a substrate, placing a semiconductor element on the coated surface of the substrate, heating and curing the heat-curable silicone-based die bonding material, removing low molecular weight siloxane components adhered to the semiconductor element, and subsequently conducting wire bonding. The adverse effects of low molecular weight siloxanes are suppressed, and highly reliable wire bonding is attained.

### BACKGROUND OF THE INVENTION

1. Field of the Invention

The present invention relates to a production method for a semiconductor device, and relates more particularly to a production method that enables the formation of highly reliable wire bonding to a semiconductor element.

2. Description of the Prior Art

Conventionally, in the production of semiconductor devices, epoxy resins have generally been used as the die bonding materials for securing semiconductor elements to substrates such as lead frames or packages. However, in the case of recently developed blue or white light emitting diodes (LED) or the like, a problem arises in that the epoxy resin-based adhesives used as the die bonding material undergo discoloration, causing a reduction in the luminance. Furthermore, in the case of structures in which multiple semiconductor elements are stacked together, because epoxy resins have a high elastic modulus, distortions caused by the stress applied to the semiconductor elements can also be a problem. Moreover, because reflow temperatures have increased with the use of lead-free solders, higher levels of heat resistance reliability may also be required of the epoxy resins.

Accordingly, the inventors of the present invention focused their attention on the use of silicone-based materials, which exhibit excellent heat resistance and a lower elastic modulus than epoxy resins, as die bonding materials.

### SUMMARY OF THE INVENTION

However, silicone-based materials usually contain low molecular weight siloxanes. With silicone-based die bonding materials, heat curing must be conducted following mounting of the semiconductor element on the substrate, but these low molecular weight siloxanes volatilize at this point and adhere to the surfaces of the semiconductor element, forming a thin coating. As a result, problems become more likely in the subsequent wire bonding step, and conducting reliable wire bonding in a stable manner is difficult.

Accordingly, an object of the present invention is to provide a production method for a semiconductor device that uses a silicone-based die bonding material, and yet enables highly reliable wire bonding to be conducted in a stable manner.

As a result of intensive investigation, the inventors of the present invention propose, as a method of resolving the problems described above,

a method for producing a semiconductor device, comprising the steps of:

applying a heat-curable silicone-based die bonding material to a substrate,

placing a semiconductor element on a coated surface of said substrate,

heating and curing said heat-curable silicone-based die bonding material,

removing low molecular weight siloxane components adhered to said semiconductor element, and

subsequently conducting wire bonding.

According to the above method, highly reliable wire bonding can be achieved with certainty, and a semiconductor device with a high level of reliability can be obtained.

### DETAILED DESCRIPTION OF THE PREFERRED EMBODIMENTS

In the production of semiconductor devices, the steps of applying a heat-curable silicone-based die bonding material to a substrate, placing a semiconductor element on the coated surface of the substrate, heating and curing the heat-curable silicone-based die bonding material, and subsequently conducting wire bonding are conventionally conducted steps.

In the method of the present invention, following the heating and curing of the die bonding material and prior to the conducting of wire bonding within the above type of production method for a semiconductor device, the low molecular weight siloxane components which are contained within the die bonding material, and which, following volatilization upon heating, become adhered to the surfaces of the semiconductor element, are removed.

—Silicone-Based Die Bonding Material—

There are no particular restrictions on the silicone-based die bonding material used in the method of the present invention. This is because silicone-based die bonding materials usually inevitably contain low molecular weight siloxanes. Silicone-based die bonding materials (for example, the curable organopolysiloxane compositions described below) that have not undergone any prior treatments or the like for removing the low molecular weight siloxane components inevitably contain from several hundred to several thousand ppm (by weight) of low molecular weight siloxane components. Here, the term “low molecular weight siloxane components” refers to organo(poly)siloxanes containing from 3 to 10 silicon atoms within each molecule, and the structure of the siloxane backbone may be a straight chain, branched, or cyclic. Particular examples include cyclic dimethylpolysiloxanes (D3 to D10) and straight-chain dimethylpolysiloxanes with both molecular chain terminals blocked with silanol groups or trimethylsiloxy groups, in which the number of repeating siloxane units (or the number of silicon atoms within each molecule) is within a range from 3 to 10.

Heat-curable silicone-based die bonding materials typically comprise an addition-curable silicone composition comprising, as essential components, (i) an alkenyl group-containing organopolysiloxane having 2 or more alkenyl groups within each molecule, (ii) an organohydrogensiloxane having 2 or more silicon atom-bonded hydrogen atoms within each molecule, and (iii) a platinum-group metal-based catalyst, and the components (i) and (ii) contain low molecular weight siloxane components. The levels of these components can be reduced at the time of production, either by conducting heat treatments or thin-film distillation treatments under reduced pressure, or by conducting treatments using solvents such as acetone or alcohols, but complete removal is impossible. Particularly in the case of so-called resin-like (three dimensional network-type) silicones, which have been subjected to three dimensional cross-linking in advance, reducing the quantity of low molecular weight siloxanes is more difficult than in the case of chain-like or cyclic organopolysiloxanes. On the other hand, these resin-like silicones are very beneficial in achieving the level of hardness required for wire bonding.

A particularly preferred example of a silicone-based die bonding material that can be used in the present invention is the composition described below.

A silicone resin composition comprising:

(A) a straight-chain organopolysiloxane having at least 2 alkenyl groups bonded to silicon atoms within each molecule, and with a viscosity at 25° C. of not more than 1,000 mPa·s,

(B) a three dimensional network-type organopolysiloxane resin that is either wax-like or solid at 23° C., represented by an average composition formula (1) shown below:

(R²₃SiO_{1/2})ₗ(R¹R²₂SiO_{1/2})ₘ(R¹R²SiO)ₙ(R²₂SiO)ₚ(R¹SiO_{3/2})_{q}(R²SiO_{3/2})ᵣ(SiO_{4/2})ₛ (1)

(wherein, each R¹ represents, independently, an alkenyl group, each R² represents, independently, an unsubstituted or substituted monovalent hydrocarbon group that contains no alkenyl groups, provided that at least 80 mol % of all the R² groups are methyl groups, and l, m, n, p, q, r, and s are numbers that satisfy 1≧0, m≧0, n≧0, p≧0, q≧0, r≧0, and s≧0 respectively, and also satisfy m+n+q>0, +r+s>0, and l+m+n+p+q+r+s=1), in sufficient quantity to provide from 60 to 90 parts by mass of the component (B) per 100 parts by mass of the combination of the component (A) and the component (B),

(C) an organohydrogenpolysiloxane having at least 2 hydrogen atoms bonded to silicon atoms within each molecule, represented by an average composition formula (2) shown below:

R³ₐH_{b}SiO_{(4-a-b)/2} (2)

(wherein, each R³ represents, independently, an unsubstituted or substituted monovalent hydrocarbon group that contains no alkenyl groups, provided that at least 50 mol % of all R³ groups are methyl groups, a is a number that satisfies 0.7≦a≦2.1, b is a number that satisfies 0.001≦b≦1.0, and a+b represents a number that satisfies 0.8≦a+b≦3.0), in sufficient quantity that a ratio of hydrogen atoms bonded to silicon atoms within the component (C) relative to the combined total of all silicon atom-bonded alkenyl groups within the component (A) and the component (B) is a molar ratio within a range from 0.5 to 5.0, and

(D) an effective quantity of a platinum-group metal-based catalyst.

Next is a more detailed description of the above composition.

This composition comprises the components (A) through (D) described below.

As follows is a detailed description of each component. In the following description, “Me” represents a methyl group, and “Vi” represents a vinyl group.

<Component (A)>

The component (A) is a component for imparting stress relaxation following curing of the composition. The component (A) is an organopolysiloxane with a basically straight-chain molecular structure, in which the principal chain typically comprises repeated diorganosiloxane units and both the molecular chain terminals are blocked with triorganosiloxy groups, wherein the structure contains at least 2, and preferably from 2 to 10, and even more preferably from 2 to 5, alkenyl groups bonded to silicon atoms within each molecule, and the viscosity at 25° C. is not more than 1,000 mPa·s (typically within a range from 1 to 1,000 mPa·s), and preferably not more than 700 mPa·s (for example, from 5 to 700 mPa·s). If the viscosity exceeds 1,000 mPa·s, then this component becomes overly active as a soft segment, meaning obtaining the targeted degree of hardness becomes difficult.

The alkenyl groups bonded to silicon atoms typically contain from 2 to 8, and preferably from 2 to 4, carbon atoms. Specific examples of these groups include vinyl groups, allyl groups, butenyl groups, pentenyl groups, hexenyl groups, and heptenyl groups, although vinyl groups are preferred.

Within the organopolysiloxane molecule of the component (A), these alkenyl groups bonded to silicon atoms may exist either at the molecular chain terminals or at non-terminal positions within the molecular chain (that is, molecular chain side chains), or may also exist at both these locations, although structures in which the alkenyl groups exist at least at both molecular chain terminals are preferred.

In the organopolysiloxane molecule of the component (A), there are no particular restrictions on organic groups bonded to silicon atoms other than the aforementioned alkenyl groups, provided these organic groups contain no aliphatic unsaturated bonds, and examples of these groups include unsubstituted or substituted monovalent hydrocarbon groups, typically of 1 to 12, and preferably of 1 to 10, carbon atoms. Specific examples of these unsubstituted or substituted monovalent hydrocarbon groups include alkyl groups such as methyl groups, ethyl groups, propyl groups, butyl groups, pentyl groups, hexyl groups, and heptyl groups; cycloalkyl groups such as cyclohexyl groups; aryl groups such as phenyl groups, tolyl groups, xylyl groups, and naphthyl groups; aralkyl groups such as benzyl groups and phenethyl groups; and groups in which either a portion of, or all of, the hydrogen atoms within these groups have been substituted with a halogen atom such as a chlorine atom, fluorine atom, or bromine atom, including halogenated alkyl groups such as chloromethyl groups, 3-chloropropyl groups, and 3,3,3-trifluoropropyl groups, although of these, alkyl groups are preferred, and methyl groups are particularly desirable.

Examples of the organopolysiloxane of the component (A) include compounds represented by an average composition formula (3) shown below:

R⁴_{c}R⁵_{d}SiO_{(4-c-d)/2} (3)

(wherein, each R⁴ represents, independently, an unsubstituted or substituted monovalent hydrocarbon group that contains no aliphatic unsaturated bonds, each R⁵ represents, independently, an alkenyl group, c represents a number from 1.9 to 2.1, and d represents a number from 0.005 to 1.0, provided that c+d satisfies a range from 1.95 to 3.0).

In the average composition formula (3) above, the unsubstituted or substituted monovalent hydrocarbon groups that contain no aliphatic unsaturated bonds represented by R⁴ are similar to those groups listed above as examples of silicon atom-bonded organic groups other than the aforementioned alkenyl groups.

The alkenyl groups represented by R⁵ are similar to those groups listed above as examples of the aforementioned alkenyl groups bonded to silicon atoms.

c is preferably a number from 1.95 to 2.00, d is preferably a number from 0.01 to 0.5, and c+d preferably satisfies a range from 1.98 to 2.5.

Examples of the organopolysiloxane of the component (A) include compounds represented by general formulas (4) and (5) shown below:

Vi(R⁶)₂SiO[Si(R⁶)₂O]ₑSi(R⁶)₂Vi (4)

Vi(R⁶)₂SiO[Si(R⁶)ViO]_{f}[Si(R⁶)₂O]_{g}Si(R⁶)₂Vi (5)

(wherein, each R⁶ represents, independently, an unsubstituted or substituted monovalent hydrocarbon group that contains no aliphatic unsaturated bonds, e represents an integer within a range from 0 to 200, and preferably from 3 to 120, f represents an integer within a range from 1 to 10, and preferably from 1 to 5, and g represents an integer within a range from 0 to 200, and preferably from 3 to 110, and these definitions also apply below), as well as compounds represented by the general formulas shown below:

(Vi)₂(R⁶)SiO[Si(R⁶)₂O]ₑSi(R⁶)(Vi)₂

(Vi)₃SiO[Si(R⁶)₂O]ₑSi(Vi)₃

(Vi)₂(R⁶)SiO[Si(R⁶)(Vi)O]_{f}[Si(R⁶)₂O]_{g}Si(R⁶)(Vi)₂

(Vi)₃SiO[Si(R⁶)(Vi)O]_{f}[Si(R⁶)₂O]_{g}Si(Vi)₃

(R⁶)₃SiO[Si(R⁶)(Vi)O]_{f}[Si(R⁶)₂O]_{g}Si(R⁶)₃

Specific examples of the component (A) include compounds with the average molecular formulas shown below.

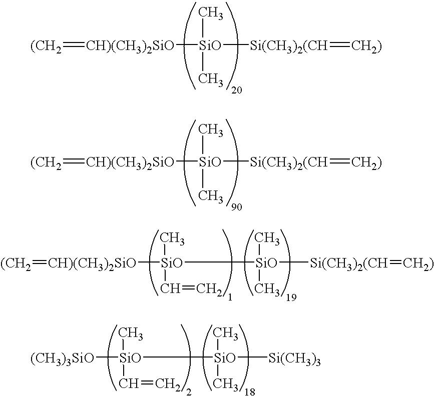

In the above general formulas, the unsubstituted or substituted monovalent hydrocarbon groups represented by R⁶ preferably contain from 1 to 10, and even more preferably from 1 to 6, carbon atoms. Specific examples of preferred groups include similar groups to those listed above as examples of organic groups bonded to silicon atoms other than the alkenyl groups, with the exception of the aryl groups and aralkyl groups, although alkyl groups are preferred, and methyl groups are particularly desirable, as they yield superior levels of light resistance and heat resistance for the cured product.

The component (A) may be used either alone, or in combinations of two or more different compounds.

<Component (B)>

The component (B) is a component for providing reinforcement while retaining the transparency of the cured product. The component (B) is represented by the average composition formula (1) shown above, and is a three dimensional network-type organopolysiloxane resin which is wax-like or solid at 23° C., and comprises alkenyl groups bonded to silicon atoms, trifunctional siloxane units, and/or SiO_{4/2} units as essential structures within the molecule. The term “wax-like” refers to a gum-like (crude rubber-like) form that exhibits almost no self-fluidity and has a viscosity at 23° C. of at least 10,000,000 mPa·s, and particularly 100,000,000 mPa·s or higher.

In the above average composition formula (1), the alkenyl groups represented by R¹ are similar to those groups listed above as examples of the alkenyl groups bonded to silicon atoms within the component (A), although in terms of ease of availability and cost, vinyl groups are preferred.

The monovalent hydrocarbon groups that contain no alkenyl groups represented by R² are similar to those groups listed above as examples of organic groups bonded to silicon atoms other than the alkenyl groups within the component (A), although at least 80 mol % (from 80 to 100 mol %), typically from 90 to 100 mol %, and even more typically from 98 to 100 mol %, of all the R² groups are methyl groups. If the proportion of methyl groups is less than 80 mol % of all the R groups, then the compatibility with the component (A) deteriorates, which can cause the composition to become turbid, making it impossible to obtain the desired highly transparent cured product.

1 is preferably a number from 0 to 0.65, m is preferably from 0 to 0.65, n is preferably from 0 to 0.5, p is preferably from 0 to 0.5, q is preferably from 0 to 0.8, r is preferably from 0 to 0.8, and s is preferably from 0 to 0.6. Furthermore, m+n+q is preferably a number within a range from 0.1 to 0.8, and even more preferably from 0.2 to 0.65, and q+r+s is preferably a number within a range from 0.1 to 0.8, and even more preferably from 0.2 to 0.6.

In the component (B), the quantity of alkenyl groups bonded to silicon atoms is preferably within a range from 0.01 to 1 mol, and even more preferably from 0.05 to 0.5 mols, per 100 g of the component (B). Provided the quantity of alkenyl groups satisfies this range from 0.01 to 1 mol, the cross-linking reaction proceeds adequately, enabling a cured product with a higher degree of hardness to be obtained.

The organopolysiloxane resin of the component (B) is preferably represented by one of the formulas shown below.

(R²₃SiO_{1/2})ₗ(R¹R²₂SiO_{1/2})ₘ(SiO_{4/2})ₛ

(R₁R²₂SiO_{1/2})ₘ(SiO_{4/2})ₛ

(R¹R²SiO)ₙ(R²₂SiO)ₚ(R²SiO_{3/2})ᵣ

(R¹R²₂SiO_{1/2})ₘ(R²₂SiO)ₚ(R¹SiO_{3/2})_{q}

(R¹R²₂SiO_{1/2})ₘ(R²₂SiO)ₚ(R²SiO_{3/2})ᵣ

(R²₃SiO_{1/2})ₗ(R¹R²₂SiO_{1/2})ₘ(R²₂SiO)ₚ(R²SiO_{3/2})ᵣ

(R²₃SiO_{1/2})ₗ(R¹R²₂SiO_{1/2})ₘ(R²₂SiO)ₚ(R¹R²SiO)ₙ(R²SiO_{3/2})ᵣ

(wherein, R¹, R², l, m, n, p, q, r, and s are all as defined above in relation to the average composition formula (1))

Specific examples of the component (B) include the compounds shown below.

(Me₃SiO_{1/2})_{0.4}(ViMe₂SiO_{1/2})_{0.1}(SiO_{4/2})_{0.5}

(ViMeSiO)_{0.4}(Me₂SiO)_{0.15}(MeSiO_{3/2})_{0.45}

(ViMe₂SiO_{1/2})_{0.2}(Me₂SiO)_{0.25}(MeSiO_{3/2})_{0.55}

The ratio of the component (B) relative to the component (A) is an important factor within the above composition. The blend quantity of the component (B) must be within a range from 60 to 90 parts by mass, preferably from 65 to 80 parts by mass, and even more preferably from 65 to 75 parts by mass, per 100 parts by mass of the combination of the component (A) and the component (B). If the blend quantity of the component (B) is less than 60 parts by mass, the targeted degree of hardness may be unattainable, whereas if the quantity exceeds 90 parts by mass, the viscosity of the composition increases markedly, making use of the composition as a die bonding material for LED elements and the like problematic.

The component (B) may be used either alone, or in combinations of two or more different compounds.

<Component (C)>

The component (C) functions as a cross-linking agent that undergoes cross-linking with the alkenyl groups within the component (A) and the component (B) via a hydrosilylation reaction, and also functions as a reactive diluent that dilutes the composition to a viscosity best suited to the intended application. The component (C) is represented by the above average composition formula (2), and is an organohydrogenpolysiloxane having at least 2, (typically from 2 to 200), and preferably 3 or more (for example, from 3 to approximately 100) hydrogen atoms bonded to silicon atoms (that is, SiH groups) within each molecule.

The viscosity at 25° C. of the organohydrogenpolysiloxane of the component (C) is preferably not more than 1,000 mPa·s (typically from 1 to 1,000 mPa·s), and is even more preferably from 5 to 200 mPa·s.

In the component (C), the quantity of the aforementioned hydrogen atoms bonded to silicon atoms is preferably within a range from 0.001 to 0.02 mols, and even more preferably from 0.002 to 0.017 mols, per 1 g of the component (C).

In the average composition formula (2), the unsubstituted or substituted monovalent hydrocarbon groups that contain no alkenyl groups represented by R³ are similar to those groups listed above as examples of silicon atom-bonded organic groups other than the alkenyl groups within the component (A), although at least 50 mol %, and typically from 60 to 100 mol %, of all the R³ groups are methyl groups. If the proportion of methyl groups is less than 50 mol % of all the R³ groups, then the compatibility with the component (A) and the component (B) deteriorates, which can cause the composition to become turbid or undergo phase separation.

a is preferably a number from 1.0 to 2.0, b is preferably from 0.01 to 1.0, and a+b is preferably a number from 1.1 to 2.6.

The 2 or more, and preferably 3 or more, hydrogen atoms bonded to silicon atoms (that is, SiH groups) within each molecule may be positioned either at the molecular chain terminals or at non-terminal positions within the molecular chain, or may also be positioned at both these locations. Furthermore, the molecular structure of this organohydrogenpolysiloxane may be any one of a straight-chain, cyclic, branched, or three dimensional network structure, although the number of silicon atoms within the molecule (or the polymerization degree) is typically within a range from 2 to 400, preferably from 3 to 200, and even more preferably from 4 to approximately 100.

Specific examples of the organohydrogenpolysiloxane of the component (C) include 1,1,3,3-tetramethyldisiloxane, 1,3,5,7-tetramethylcyclotetrasiloxane, tris(hydrogendimethylsiloxy)methylsilane, tris(hydrogendimethylsiloxy)phenylsilane, methylhydrogencyclopolysiloxane, cyclic copolymers of methylhydrogensiloxane and dimethylsiloxane, methylhydrogenpolysiloxane with both molecular chain terminals blocked with trimethylsiloxy groups, copolymers of dimethylsiloxane and methylhydrogensiloxane with both terminals blocked with trimethylsiloxy groups, dimethylpolysiloxane with both terminals blocked with dimethylhydrogensiloxy groups, copolymers of dimethylsiloxane and methylhydrogensiloxane with both terminals blocked with dimethylhydrogensiloxy groups, copolymers of methylhydrogensiloxane and diphenylsiloxane with both terminals blocked with trimethylsiloxy groups, copolymers of methylhydrogensiloxane, diphenylsiloxane, and dimethylsiloxane with both terminals blocked with trimethylsiloxy groups, copolymers of methylhydrogensiloxane, methylphenylsiloxane, and dimethylsiloxane with both terminals blocked with trimethylsiloxy groups, copolymers of methylhydrogensiloxane, dimethylsiloxane, and diphenylsiloxane with both terminals blocked with dimethylhydrogensiloxy groups, copolymers of methylhydrogensiloxane, dimethylsiloxane, and methylphenylsiloxane with both terminals blocked with dimethylhydrogensiloxy groups, copolymers formed of (CH₃)₂HSiO_{1/2} units, (CH₃)₃SiO_{1/2} units, and SiO_{4/2} units, copolymers formed of (CH₃)₂HSiO_{1/2} units and SiO_{4/2} units, and copolymers formed of (CH₃)₂HSiO_{1/2} units, SiO_{4/2} units, and (C₆H₅)₃SiO_{1/2} units, as well as compounds represented by general formulas (6) and (7) shown below:

R³₃SiO[SiR³(H)O]ₜSiR³₃ (6)

cyclic[SiR³(H)O]ᵤ (7)

(wherein, R³ is as defined above, t represents an integer from 2 to 30, and preferably from 2 to 25, and u represents an integer from 4 to 8), and compounds represented by the general formulas shown below:

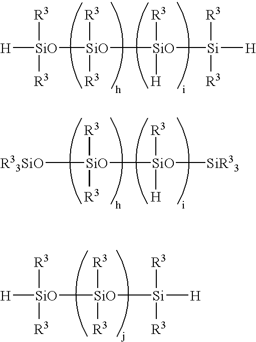

(wherein, R³ is as defined above, h represents an integer from 5 to 40, i represents an integer from 5 to 20, and j represents an integer from 2 to 30).

Specific examples of the component (C) include compounds represented by the general formula (8) shown below:

Me₃SiO[SiMe(H)O]ₜSiMe₃ (8)

(wherein, t is as defined above),
and compounds represented by the average structural formulas shown below.

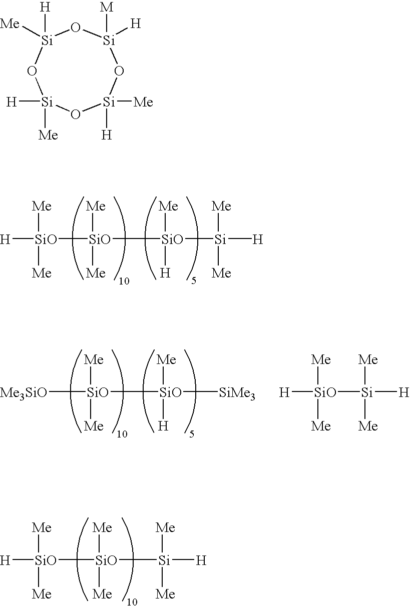

The blend quantity of the component (C) must be sufficient that the ratio of hydrogen atoms bonded to silicon atoms within the component (C) relative to the combined total of all silicon atom-bonded alkenyl groups within the component (A) and the component (B) is a molar ratio within a range from 0.5 to 5.0, and is preferably a ratio from 0.7 to 3.0. If this blend quantity does not satisfy this molar range from 0.5 to 5.0, then the cross-linking balance may become unsatisfactory.

In a preferred embodiment, the blend quantity of the component (C) is sufficient that the ratio of hydrogen atoms bonded to silicon atoms within the component (C) relative to the combined total of all silicon atom-bonded alkenyl groups within the entire composition is a molar ratio within a range from 0.6 to 3.0, and even more preferably from 0.7 to 2.0. If this range is satisfied, then a composition with a viscosity that is ideal for subsequent use is obtained, and a cured product with the targeted degree of hardness can also be obtained.

The component (C) may be used either alone, or in combinations of two or more different compounds.

<Component (D)>

The platinum-group metal-based catalyst of the component (D) is a component for promoting and accelerating the hydrosilylation reaction between the aforementioned components (A) through (C).

There are no particular restrictions on the platinum-group metal-based catalyst, and suitable examples include platinum-group metals such as platinum, palladium, and rhodium; platinum compounds such as chloroplatinic acid, alcohol-modified chloroplatinic acid, and coordination compounds of chloroplatinic acid with olefins, vinylsiloxane, or acetylene compounds; and platinum-group metal compounds such as tetrakis(triphenylphosphine)palladium and chlorotris(triphenylphosphine)rhodium, although of these, a silicone-modified chloroplatinic acid is preferred, as it exhibits favorable compatibility with the components (A) through (C), and contains almost no chlorine impurities.

The blend quantity of the component (D) need only be an effective catalytic quantity, and a typical quantity, calculated as the mass of the platinum-group metal element relative to the combined mass of the components (A) through (C), is within a range from 3 to 100 ppm, and quantities from 5 to 40 ppm are preferred. By using an appropriate blend quantity, the hydrosilylation reaction can be accelerated effectively.

The component (D) may be used either alone, or in combinations of two or more different compounds.

<Other Components>

In addition to the components (A) through (D) described above, other components such as those described below can also be added to the composition described above, provided such addition does not impair the object of the present invention.

Examples of these other components include thixotropic control agents such as fumed silica; light scattering agents such as crystalline silica; reinforcing materials such as fumed silica or crystalline silica; phosphors; viscosity control agents such as petroleum-based solvents and unreactive silicone oils that contain no reactive functional groups; adhesion improvers such as silicone compounds other than the components (A) through (C) which contain at least one of a carbon functional silane, epoxy group, alkoxy group, silicon atom-bonded hydrogen atom (that is, SiH group), and an alkenyl group such as a vinyl group bonded to a silicon atom; conductivity-imparting agents such as metal powders of silver or gold or the like; pigments and dyes used for coloring; and reaction retarders such as tetramethyltetravinylcyclotetrasiloxane.

These other components may be used either alone, or in combinations of two or more different materials.

### <Preparation and Curing of Composition>

In the composition described above, the fact that at least 80 mol % (80 to 100 mol %), and preferably 90 mol % or more (90 to 100 mol %), of all the monovalent hydrocarbon groups bonded to silicon atoms other than alkenyl groups are methyl groups ensures superior heat resistance and light resistance (ultraviolet light resistance), meaning the composition exhibits excellent resistance to deterioration, including discoloration, resulting from stress caused by heat or ultraviolet light.

Preparation Method

The above composition can be prepared by mixing together the components (A) through (D), and any other optional components as required, and in one suitable example, can be prepared by first preparing a part comprising the component (A) and the component (B), and a part comprising the component (C), the component (D) and any other components that may be used, and subsequently mixing these two parts together.

Curing Conditions

Curing of the composition can be conducted under conventional conditions, and for example, can be conducted by heating at a temperature of 60 to 180° C. for a period of 10 minutes to 3 hours. In particular, the Shore D hardness of the cured product obtained by curing the composition is preferably at least 30, and even more preferably 50 or higher, and curing conditions for ensuring the Shore D hardness is at least 30 can usually be obtained by heating and curing the above composition at 120 to 180° C. for a period of 30 minutes to 3 hours.

Die Bonding

In the method of the present invention, the heat-curable silicone-based die bonding material is applied to a substrate, a semiconductor element is placed on the coated surface of the substrate, and the die bonding material is then heated and cured.

Examples of substrates that can be used include, for example, lead frames and packages.

Examples of suitable semiconductor elements include LED elements and light-receiving elements.

In one example of a method of die bonding a semiconductor element using a die bonding material, the die bonding material is first used to fill a syringe, the die bonding material is applied to the surface of a substrate such as a package using a dispenser, in sufficient quantity to generate a dried coating of thickness 5 to 100 μm, the element is placed on top of the applied die bonding material, and the die bonding material is cured, thereby die bonding the semiconductor element to the substrate.

—Removal of Low Molecular Weight Siloxane Components—

Following curing of the die bonding material, low molecular weight siloxanes have adhered to the surfaces of the semiconductor element. Examples of methods of removing these siloxanes include 1) a method in which the semiconductor element to which the low molecular weight siloxanes are adhered is cleaned with a solvent, and 2) a method in which the semiconductor element to which the low molecular weight siloxanes are adhered is subjected to a plasma treatment.

Examples of solvents that can be used in the solvent cleaning method 1) include aromatic solvents such as toluene and xylene; aliphatic hydrocarbon-based solvents such as heptane, hexane and mineral spirit; and polar organic solvents such as acetone, isopropyl alcohol and methyl ethyl ketone, and these solvents may be used either alone, or in combinations of two or more different solvents. Specific examples of methods of cleaning using a solvent include, for example, a method in which the semiconductor element is simply immersed in the solvent, is subsequently removed from the solvent, and the residual solvent on the element surfaces is dried and removed, a method in which the solvent is washed over the semiconductor element, and the residual solvent on the element surfaces is then dried and removed, and a method in which the semiconductor element is subjected to an ultrasonic cleaning treatment while immersed within the solvent, is subsequently removed from the solvent, and the residual solvent on the element surfaces is dried and removed.

Examples of the plasma used in the plasma treatment method 2) include an argon gas plasma and an oxygen plasma.

—Wire Bonding—

Following removal of the low molecular weight siloxane components, wire bonding is conducted. There are no particular restrictions on the wire bonding method itself, and conventional methods may be used. Because contamination of the semiconductor element surfaces by low molecular weight siloxane components has been removed in the step described above, highly reliable wire bonding can be achieved in a stable manner.

### EXAMPLES

As follows is a more detailed description of the method of the present invention using a series of examples.

—Preparation of Die Bonding Material—

(1) A toluene solution of a silicone resin, formed of Me₃SiO_{1/2}, ViMe₂SiO_{1/2} and SiO_{4/2} units, with a molar ratio of the combination of the Me₃SiO_{1/2} and ViMe₂SiO_{1/2} units relative to the SiO_{4/2} units of 0.8, and with a vinyl group quantity relative to the solid fraction of 0.074 mols/100 g, was mixed with a straight-chain dimethylpolysiloxane with both terminals blocked with vinyl groups and with a viscosity at 25° C. of 50 mPa·s, in a solid fraction ratio of 75:25 (by mass). The toluene was removed from the resulting mixture by treatment at 120° C. under a reduced pressure of not more than 10 mmHg, thereby yielding a base polymer component that was a viscous liquid at room temperature.

100 parts by mass of this base polymer component was mixed with 3 parts by mass of tetramethyltetravinylcyclotetrasiloxane and 10 parts by mass of a methylhydrogensiloxane with both terminals blocked with trimethylsilyl groups and containing 0.015 mol/g of Si—H groups within its structure, thereby yielding a transparent liquid composition.

Immediately prior to use, a toluene solution of a platinum catalyst derived from chloroplatinic acid and containing tetramethylvinyldisiloxane ligands was added to this composition in sufficient quantity to provide a quantity of platinum atoms equivalent to 10 ppm (by mass), and the mixture was then stirred uniformly, thus yielding a die bonding material.

### Comparative Example 1

### (1) Die Bonding

A silicon wafer of thickness 0.3 mm was diced to prepare 1 mm square dummy chips. An appropriate quantity of the die bonding material was applied to a substrate prepared by using silver plating to form a pattern on an FR-4 substrate, a dummy chip was placed on top, and the die bonding material was then cured by heating at 100° C. for 1 hour, and then at 150° C. for a further 3 hours. During this process, in order to make the quantity of volatilized siloxanes large and to thereby ensure the effect on the wire bonding step, the substrate was placed on a metal plate, three aluminum Petri dishes of diameter 6 cm, each of which had been coated uniformly with 1 g of the die bonding material, were prepared and positioned around the periphery of the substrate, and the entire structure was then covered with a metal can of diameter 18 cm and height 4 cm, thereby creating an enclosed space.

### (2) Wire Bonding

When wire bonding was attempted to the semiconductor element that had undergone die bonding in the manner described above, of 20 test points, 17 resulted in wire bonding faults.

Analysis by XPS (X-ray photoelectron spectroscopy) of the semiconductor element surface following die bonding confirmed the presence of the following elements.

TABLE 1

Element

| | C | O | Si | N |
|---|---|---|---|---|
| Composition ratio (%) | 45 | 42 | 9 | 4 |

Furthermore, detailed analysis of the detected Si peak revealed that of all the Si atoms detected, 76% were derived from inorganic SiO₂, and 24% were derived from siloxanes.

### Example 1

In the comparative example 1, with the exception of immersing the solvent in toluene, conducting cleaning with an ultrasonic cleaner for 10 minutes, subsequently lifting the substrate out of the toluene, washing isopropyl alcohol across the substrate, and then conducting air drying, all of which were conducted following completion of die bonding in the same manner as in (1) above, but prior to conducting the wire bonding of (2), wire bonding was tested in the same manner as the comparative example 1. Of the 20 test points, normal wire bonding was achieved at all 20 points.

Analysis by XPS (X-ray photoelectron spectroscopy) of the semiconductor element surface following die bonding confirmed the presence of the following elements.

TABLE 2

Element

| | C | O | Si | N |
|---|---|---|---|---|
| Composition ratio (%) | 43 | 49 | 6 | 1 |

Further analysis of the Si peak in the same manner as the comparative example 1 revealed that of all the Si atoms detected, 94% were derived from SiO₂, and 6% were derived from siloxanes.

### Example 2

In the comparative example 1, with the exception of subjecting the substrate to plasma treatment using an argon plasma apparatus under conditions including an Ar gas flow rate of 100 sccm, a degree of vacuum of 0.2 Torr (26 Pa), an output of 20 W and a time of 10 seconds, which was conducted following completion of die bonding in the same manner as in (1) above, but prior to conducting the wire bonding of (2), wire bonding was tested in the same manner as the comparative example 1. Of the 20 test points, normal wire bonding was achieved at all 20 points.

Analysis by XPS (X-ray photoelectron spectroscopy) of the semiconductor element surface following die bonding confirmed the presence of the following elements.

TABLE 3

Element

| | C | O | Si | N |
|---|---|---|---|---|
| Composition ratio (%) | 22 | 66 | 10 | ND |

Further analysis of the Si peak in the same manner as the comparative example 1 revealed that of all the Si atoms detected, 100% were derived from SiO₂, and 0% were derived from siloxanes.

What is claimed is:

1. A method for producing a semiconductor device, comprising the steps of:
applying a heat-curable silicone-based die bonding material to a substrate,
placing a semiconductor element on a coated surface of said substrate,
heating and curing said heat-curable silicone-based die bonding material,
removing low molecular weight siloxane components adhered to said semiconductor element, and
subsequently conducting wire bonding.

2. The method according to claim 1, wherein said heat-curable silicone-based die bonding material is an addition-curable silicone resin composition, comprising:
(A) a straight-chain organopolysiloxane having at least 2 alkenyl groups bonded to silicon atoms within each molecule, and with a viscosity at 25° C. of not more than 1,000 mPa·s,
(B) a three dimensional network-type organopolysiloxane resin that is either wax-like or solid at 23° C., represented by an average composition formula (1) shown below:
(R²₃SiO_{1/2})ₗ(R¹R²₂SiO_{1/2})ₘ(R¹R²SiO)ₙ(R²₂SiO)ₚ(R¹SiO_{3/2})_{q}(R²SiO_{3/2})ᵣ(SiO_{4/2})ₛ (1)
(wherein, each R¹ represents, independently, an alkenyl group, each R² represents, independently, an unsubstituted or substituted monovalent hydrocarbon group that contains no alkenyl groups, provided that at least 80 mol % of all R² groups are methyl groups, and l, m, n, p, q, r, and s are numbers that satisfy 1≧0, m≧0, n≧0, p≧0, q≧0, r≧0, and s≧0 respectively, and also satisfy m+n+q>0, q+r+s>0, and l+m+n+p+q+r+s=1), in sufficient quantity to provide from 60 to 90 parts by mass of component (B) per 100 parts by mass of a combination of said component (A) and said component (B),
(C) an organohydrogenpolysiloxane having at least 2 hydrogen atoms bonded to silicon atoms within each molecule, represented by an average composition formula (2) shown below:
R³ₐH_{b}SiO_{(4-a-b)/2} (2)
(wherein, each R³ represents, independently, an unsubstituted or substituted monovalent hydrocarbon group that contains no alkenyl groups, provided that at least 50 mol % of all R³ groups are methyl groups, a is a number that satisfies 0.7≦a≦2.1, b is a number that satisfies 0.001≦b≦1.0, and a+b represents a number that satisfies 0.8≦a+b≦3.0), in sufficient quantity that a ratio of hydrogen atoms bonded to silicon atoms within component (C) relative to a combined total of all silicon atom-bonded alkenyl groups within said component (A) and said component (B) is a molar ratio within a range from 0.5 to 5.0, and
(D) an effective quantity of a platinum-group metal-based catalyst.

3. The method according to either claim 1, wherein said low molecular weight siloxane components are removed by cleaning said semiconductor element with a solvent.

4. The method according to either claim 1, wherein said low molecular weight siloxane components are removed by subjecting said semiconductor element to a plasma treatment.
